(19) United States
(12) Patent Application Publication
(10) Pub. No.: US 2025/0142896 A1
(43) Pub. Date: May 1, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Kyung-Eun BYUN, Suwon-si (KR); Baekwon PARK, Suwon-si (KR); Minsu SEOL, Suwon-si (KR); Sungil PARK, Hwaseong-si (KR); Jaehyun PARK, Hwaseong-si (KR); Min seok YOO, Suwon-si (KR)

(73) Assignee: Samsung Electronics Co., Ltd., Suwon-si (KR)

(21) Appl. No.: 18/820,588

(22) Filed: Aug. 30, 2024

(30) Foreign Application Priority Data
Nov. 1, 2023 (KR) 10-2023-0149353

(51) Int. Cl. H01L 29/76; H01L 21/02; H01L 29/06; H01L 29/24; H01L 29/423; H01L 29/66; H01L 29/775; H01L 29/786

(52) U.S. Cl. CPC H10D 48/362; H01L 21/02568; H10D 30/43; H10D 30/6735; H10D 30/6757; H10D 62/121; H10D 62/80; H10D 99/00

(57) ABSTRACT

A semiconductor device includes a metal nitride layer, a channel provided in the metal nitride layer and including a two-dimensional (2D) semiconductor material, a source electrode provided on one side of the channel, a drain electrode provided on another side of the channel, a gate insulating layer provided in the channel, and a gate electrode provided on the gate insulating layer.

### CROSS-REFERENCE TO RELATED APPLICATION

This application is based on and claims priority under 35 U.S.C. § 119 to Korean Patent Application No. 10-2023-0149353, filed on Nov. 1, 2023, in the Korean Intellectual Property Office, the disclosure of which is incorporated by reference herein in its entirety.

### BACKGROUND

### 1. Field

The disclosure relates to a semiconductor device including a channel of a two-dimensional (2D) semiconductor material and a method of manufacturing the semiconductor device.

### 2. Description of the Related Art

As miniaturization progresses to improve the degree of integration of semiconductor devices, performance limitations are emerging due to scaling of three-dimensional (3D) bulk materials. To overcome the scaling limitations, a lot of research has been conducted using two-dimensional (2D) layered materials. 2D layered materials tend to have stable and excellent properties even at a thickness of 1 nm or less, and are attracting attention as next-generation materials capable of overcoming the performance degradation limitations due to the scaling of 3D bulk materials of the related art. For example, in the case of silicon channels, a mobility degradation and a distribution of a threshold voltage Vth increase as a channel thickness decreases, and the performance degradation due to the short channel effect increases as a channel length decreases. In contrast, 2D semiconductor material channels not only have excellent performance even at a thin thickness of 1 nm or less, but also have a smaller short channel effect than silicon channels.

### SUMMARY

Provided is a semiconductor device including a channel of a two-dimensional (2D) semiconductor material provided in a metal nitride layer.

Provided is a method of manufacturing a semiconductor device forming a channel of a 2D semiconductor material in a metal nitride layer.

Additional aspects will be set forth in part in the description which follows and, in part, will be apparent from the description, or may be learned by practice of the presented embodiments of the disclosure.

According to an aspect of the disclosure, a semiconductor device includes a metal nitride layer, a channel on a surface the metal nitride layer, the channel comprising a two-dimensional (2D) semiconductor material, a source electrode on a first side of the channel, a drain electrode on a second side of the channel, a gate insulating layer on the channel, and a gate electrode on the gate insulating layer such that the gate insulating layer is between the gate electrode and the channel.

The metal nitride layer may include a transition metal and nitrogen.

The metal nitride layer may include a material expressed as M¹N, where M¹ may represent at least one of Mo, W, Nb, V, Ta, Ti, Zr, or Hf.

The metal nitride layer may have a thickness greater than 0 and about 3 nm or less.

The channel may include a material expressed as M²X₂, where M² may represent at least one of Mo, W, Nb, V, Ta, Ti, Zr, Hf, Tc, or Re, and X may represent at least one of S, Se, or Te.

The channel may include MoS₂, MoSe₂, MoTe₂, WS₂, WSe₂, WTe₂, ZrS₂, ZrSe₂, HfS₂, HfSe₂, NbSe₂, or ReSe₂.

The metal nitride layer may further include carbon.

The channel may be in direct contact with the metal nitride layer.

The channel may include a stack of 1 or more and 10 or less 2D semiconductor material layers.

According to another aspect of at least one embodiment, a method of manufacturing a semiconductor device depositing a metal layer on a surface of a metal nitride layer, forming a channel of a 2D semiconductor material by reacting a metal of the metal layer with a chalcogen element, forming a source electrode on a first side of the channel and forming a drain electrode on a second side of the channel, forming a gate insulating layer on the channel, and forming a gate electrode on the gate insulating layer such that the gate insulating layer is between the gate electrode and the channel.

The forming of the channel may be performed by a chemical vapor deposition (CVD), physical vapor deposition (PVD), or atomic layer deposition (ALD) process.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a schematic plan view of a semiconductor device according to at least one embodiment;

FIG. 1B is a cross-sectional view taken along line A-A′ of FIG. 1A;

FIG. 1C is a cross-sectional view taken along line B-B′ of FIG. 1A;

FIG. 2A is a cross-sectional view of a semiconductor device according to at least one embodiment;

FIG. 2B is a cross-sectional view taken along line C-C′ of FIG. 2A;

FIG. 3A is a cross-sectional view of a semiconductor device according to at least one embodiment;

FIG. 3B is a cross-sectional view taken along line D-D′ of FIG. 3A;

FIG. 4 is a cross-sectional view of a semiconductor device according to at least one embodiment;

FIG. 5 is a cross-sectional view taken along line E-E′ of FIG. 4;

FIG. 6 is a cross-sectional view of a semiconductor device according to at least one embodiment;

FIG. 7 is a cross-sectional view taken along line F-F′ of FIG. 6;

FIG. 8 is a cross-sectional view of a semiconductor device according to at least one embodiment;

FIG. 9 is a cross-sectional view taken along line G-G′ of FIG. 8;

FIGS. 10 and 11 are diagrams for explaining a method of manufacturing a semiconductor device according to at least one embodiment;

FIGS. 12 to 32 are cross-sectional views for explaining a method of manufacturing a semiconductor device according to at least one embodiment;

FIG. 33 is a block diagram of a display device to which a semiconductor device is applied according to at least one embodiment;

FIG. 34 is a circuit diagram of a memory device to which a semiconductor device is applied according to at least one embodiment; and

FIG. 35 is a block diagram of an electronic device to which a semiconductor device is applied according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and a method of manufacturing the semiconductor device according to some embodiments are described in detail with reference to the attached drawings. In the drawings, like reference numerals in the drawings denote like elements, and sizes of components in the drawings may be exaggerated for clarity and convenience of explanation. While such terms as “first,” “second,” etc., may be used to describe various components, such components must not be limited to the above terms as such terms are used only to distinguish one component from another.

When the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Hereinafter, the term “upper portion” or “on” may also include “to be present on a non-contact basis” as well as “to be in directly contact with”. Additionally, it will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. An expression used in the singular encompasses the expression of the plural, unless it has a clearly different meaning in the context. When a portion “includes” a component, another component may be further included, rather than excluding the existence of the other component, unless otherwise described. Sizes or thicknesses of components in the drawings may be arbitrarily exaggerated for convenience of explanation. Further, when a certain material layer is described as being arranged on a substrate or another layer, the material layer may be in contact with the other layer, or there may be a third layer between the material layer and the other layer. In the following embodiment, materials constituting each layer are provided merely as an example, and other materials may also be used.

Further, the terms functional blocks representing units that processes at least one function or operation, may be implemented in processing circuitry such as hardware, software, and/or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

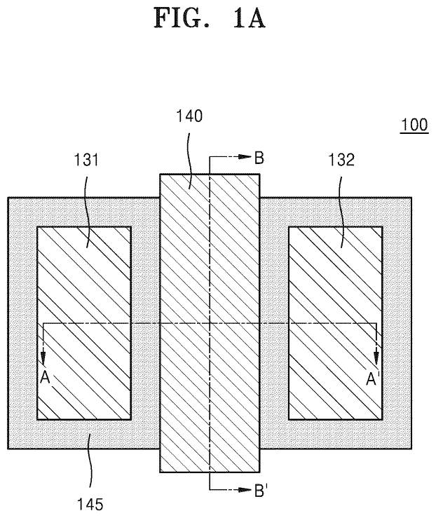

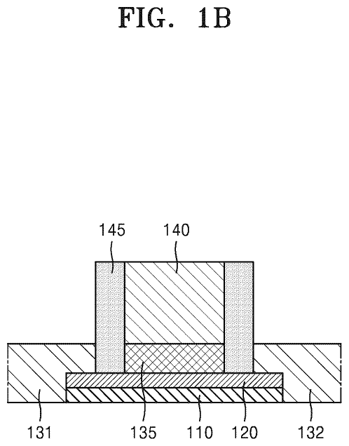

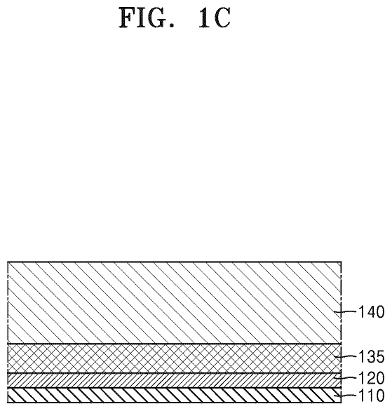

FIG. 1A is a schematic plan view of a semiconductor device 100 according to at least one embodiment. FIG. 1B is a cross-sectional view taken along line A-A′ of FIG. 1A. FIG. 1C is a cross-sectional view taken along line B-B′ of FIG. 1A.

The semiconductor device 100 includes a metal nitride layer 110, a channel 120 provided in the metal nitride layer 110, a source electrode 131 provided on one side of the channel 120, a drain electrode 132 provided on the other side of the channel 120, a gate insulating layer 135 provided on the channel 120, and a gate electrode 140 provided on the gate insulating layer 135.

In at least one embodiment, the insulator 145 may be further provided each between the source electrode 131 and the gate electrode 140 and between the drain electrode 132 and the gate electrode 140. In at least one embodiment, the insulator 145 may be provided to surround the source electrode 131 and the drain electrode 132.

The metal nitride layer 110 may include a metal and nitrogen. The metal nitride layer 110 may be expressed, for example, as M¹N, where M¹ represents the metal and N represents nitrogen. M¹ may include, for example, a transition metal. M¹ may include at least one of Mo, W, Nb, V, Ta, Ti, Zr, or Hf; and the metal nitride layer 110 may include at least one of MoN, WN, NbN, VN, TaN, TiN, ZrN, or HfN.

Alternatively, the metal nitride layer 110 may further include carbon. In this case, the metal nitride layer 110 may be expressed as M¹NC wherein C represents carbon.

The metal nitride layer 110 may serve to increase a grain size of the channel 120, and as a result, performance of the channel 120 does not deteriorate even when a thickness of the channel 120 is thin, thereby mitigating and preventing, e.g., a mobility degradation due to a reduction in the thickness of the channel 120, reducing a distribution of a threshold voltage Vth, and/or reducing the short channel effect according to a reduction in a length of the channel 120. The metal nitride layer 110 may have a thickness greater than 0 and 3 nm or less. In at least one embodiment, the metal nitride layer 110 may have a thickness greater than 0 and 2 nm or less.

The channel 120 may include a two-dimensional (2D) semiconductor material. The channel 120 may have a thickness greater than 0 and 3 nm or less. The channel 120 may have a thickness greater than 0 and 2 nm or less. The channel 120 may be provided to be in direct contact with the metal nitride layer 110.

The 2D semiconductor material refers to a semiconductor material with a 2D crystal structure and may have a monolayer or multilayer structure. The 2D semiconductor material may have excellent electrical characteristics, and maintains high mobility even when the thickness of the 2D semiconductor material is reduced to the nano scale, and thus may be applied to various devices. Each layer constituting the 2D semiconductor material may have a thickness of an atomic level. The channel 120 may include 1 to 10 2D semiconductor material layers. The 2D semiconductor material layers may each extend in directions parallel to the upper surface of the metal nitride layer 110, and may be stacked in a direction perpendicular to the upper surface of the metal nitride layer 110.

The 2D semiconductor material may include, for example, at least one of graphene, black phosphorous, or a transition metal dichalcogenide (TMD). Graphene, which is a material that has a hexagonal honeycomb structure in which carbon atoms are 2D bonded through sp² hybridized bonds, has the advantages of high electrical mobility, excellent thermal properties, chemical stability, and a large surface area (e.g., compared to silicon (Si)). Also, black phosphorus is a material in which black phosphorous atoms are 2D bonded.

TMD may be expressed, for example, as M²X₂, where M²X₂ represents a transition metal and X represents a chalcogen element. For example, M² may be Mo, W, Nb, V, Ta, Ti, Zr, Hf, Tc, or Re, and X may be S, Se, or Te. Thus, for example, the TMD may include MoS₂, MoSe₂, MoTe₂, WS₂, WSe₂, WTe₂, ZrS₂, ZrSe₂, HfS₂, HfSe₂, NbSe₂, ReSe₂, and/or the like. In at least one embodiment the metals M¹ and M² may be the same metal. In another embodiment, the metals M¹ and M² may be the different metals.

Alternatively, the 2D semiconductor material may include CuS, which is a compound of Cu, a transition metal, and S, a chalcogen element. Meanwhile, the 2D semiconductor material may be a chalcogenide material containing a non-transition metal. The non-transition metal may include, for example, Ga, In, Sn, Ge, Pb, etc. In these cases, the 2D semiconductor material may include a compound of non-transition metal such as Ga, In, Sn, Ge, Pb, etc. and a chalcogen element such as S, Se, and Te. For example, the 2D semiconductor material may include SnSe₂, GaS, GaSe, GaTe, GeSe, In₂Se₃, InSnS₂, and/or the like. However, the materials mentioned above are merely examples, and other materials may be used as the 2D semiconductor material.

The 2D semiconductor material may be doped with p-type dopant or n-type dopant to control mobility. Here, the p-type dopant and n-type dopant may be, for example, p-type dopant and n-type dopant used in, e.g., graphene (and/or carbon nanotube (CNT)), and/or selected based on the 2D semiconductor material. The p-type dopant or n-type dopant may be doped by using ion implantation or chemical doping.

The gate insulating layer 135 may be configured to electrically insulate and suppress leakage current between the channel 120 and the gate electrode 140. For example, the gate insulating layer 135 may include an insulator, such as at least one of low-doped silicon, SiO₂, Al₂O₃, HfO₂, Si₃N₄, and/or the like. The gate insulating layer 135 may also (e.g., alternatively and/or in addition to) include a high-k dielectric material, which is a material with a higher dielectric constant compared to SiO₂. The gate insulating layer 135 may include, for example, aluminum oxide, hafnium oxide, zirconium hafnium oxide, or lanthanum oxide. However, the gate insulating layer 135 is not limited thereto and may include various types of insulating materials.

The source electrode 131 and the drain electrode 132 may include a metal material and/or a metallically conductive material having electrical conductivity. For example, the source electrode 131 and the drain electrode 132 may each include magnesium (Mg), aluminum (Al), scandium (Sc), titanium (Ti), vanadium (V), chromium (Cr), manganese (Mn), nickel (Ni), copper (Cu), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), a combination thereof, and/or the like.

The gate electrode 140 may include a metal material, a conductive oxide, and/or an otherwise metallically conductive material. Here, the metal material may include, for example, Au, Ti, TiN, TaN, W, Mo, WN, Pt or Ni, a combination thereof, and/or the like. The conductive oxide may include, for example, Indium Tin Oxide (ITO), Indium Zinc Oxide (IZO), and/or the like. Alternatively, the gate electrode 140 may include the same material as that of each of the source electrode 131 and the drain electrode 132.

The semiconductor device 100 according to at least one embodiment may include the channel 120 of the 2D semiconductor material on the metal nitride layer 110 to increase the grain size of the channel 120. A grain refers to an area where crystals are oriented in one direction, and boundaries between grains deteriorate the physical properties of a device. Therefore, as the grain size of the channel 120 increases, the physical characteristics of the device may be enhanced. When the thickness of the channel 120 is thick, the grain size may be increased. However, as the semiconductor device 100 is scaled down, the thickness of the channel 120 is very thin, making it difficult to increase the grain size. The metal nitride layer 110 may increase the grain size while reducing the thickness of the channel 120.

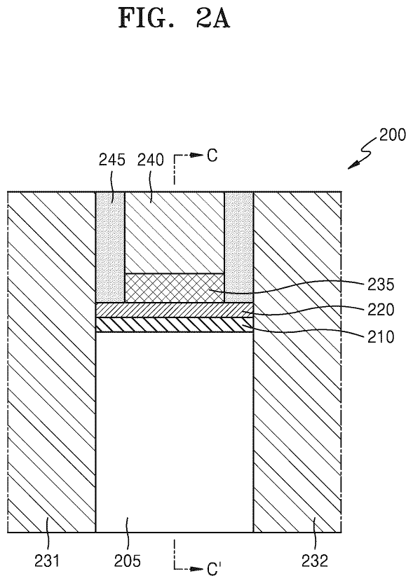

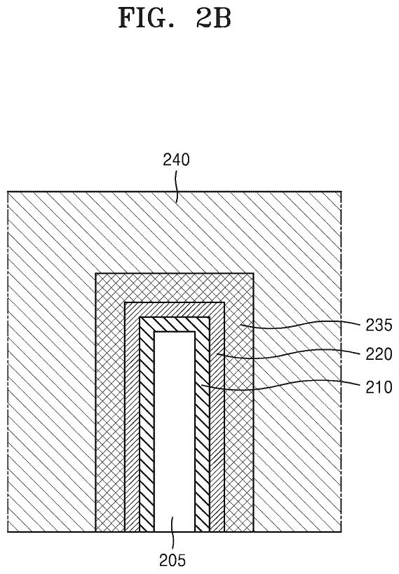

FIG. 2A is a cross-sectional view of a semiconductor device 200 according to at least one embodiment. FIG. 2B is a cross-sectional view taken along line C-C′ of FIG. 2A.

Referring to FIG. 2A, the semiconductor device 200 includes a substrate 205, a metal nitride layer 210 provided on the substrate 205, a channel 220 provided on the metal nitride layer 210, a source electrode 231 provided on one side of the channel 220, a drain electrode 232 provided on the other side of the channel 220, a gate insulating layer 235 provided on the channel 220, and a gate electrode 240 provided on the gate insulating layer 235.

A thickness of each of the source electrode 231 and the drain electrode 232 may extend from a lower surface of the substrate 205 to an upper surface of the gate electrode 240. An insulator 245 may be provided between the source electrode 231 and the gate electrode 240 and between the drain electrode 232 and the gate electrode 240.

In at least one embodiment, the substrate 205 may include, for example, silicon (Si), such as single crystalline silicon, polycrystalline silicon, or amorphous silicon. In at least one embodiment, the substrate 205 may include a group IV semiconductor such as germanium (Ge), a group IV-IV compound semiconductor such as silicon germanium (SiGe) or silicon carbide (SiC), or a group III-V compound semiconductor such as gallium arsenide (GaAs), indium arsenide (InAs), indium phosphide (InP), etc. The substrate 205 may be based on a silicon (Si) bulk substrate or a silicon on insulator (SOI) substrate. However, the substrate 205 is not limited to the bulk or SOI substrate, and may be a substrate based on an epitaxial wafer, a polished wafer, an annealed wafer, and/or the like.

The substrate 205 may include a conductive region, for example, a well doped with impurities, or various structures doped with impurities. In addition, the substrate 205 may be configured as a p-type substrate or an n-type substrate according to the type of impurity ion to be doped.

Materials of elements with the same names as those described with reference to FIGS. 1A, 1B, and 1C may be here applied to the semiconductor device 200, and differences from the semiconductor device 100 are mainly described. Meanwhile, in the specification, in order to avoid the redundant descriptions, even though the member reference numerals are different, the descriptions with reference to FIGS. 1A, 1B, and 1C are equally applied to the elements with the same names, unless otherwise specified.

Referring to FIG. 2B, the metal nitride layer 210 may be provided to surround at least three sides of the substrate 205, and the channel 220 may be provided to cover the entire metal nitride layer 210. For example, the metal nitride layer 210 may be provided to extend along a top surface of the substrate 205 and along two opposing sides adjoined to the top surface. The gate insulating layer 235 may be provided to surround three sides of the channel 220. Referring to FIGS. 2A and 2B together, the gate insulating layer 235 may be provided to partially surround the three sides of the channel 220. The gate electrode 240 may be provided to surround the gate insulating layer 235. In the semiconductor device 200, the gate electrode 240 may be provided to face the three sides of the channel 220. As a facing area of the gate electrode 240 and the channel 220 increases, the short channel effect may be reduced, and leakage current may be reduced, and thus, the performance of the semiconductor device 200 may be increased.

The semiconductor device 200 includes the channel 220 including a 2D semiconductor material in the metal nitride layer 210, thereby preventing the grain size from being reduced even when the thickness of the channel 220 is very thin. The semiconductor device 200 may be employed in a Fin Field Effect Transistor (FET).

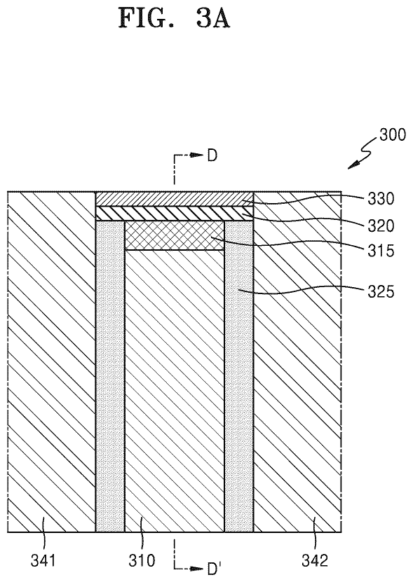

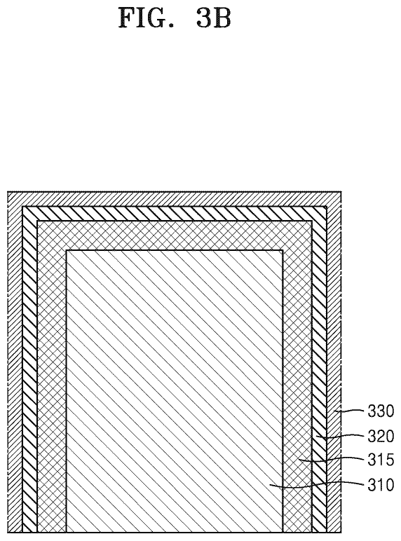

FIG. 3A is a cross-sectional view of a semiconductor device 300 according to at least one embodiment. FIG. 3B is a cross-sectional view taken along line D-D′ of FIG. 3A.

Referring to FIG. 3A, the semiconductor device 300 includes a gate electrode 310, a gate insulating layer 315 provided on the gate electrode 310, a metal nitride layer 320 provided on the gate insulating layer 315, a channel 330 provided on the metal nitride layer 320, a source electrode 341 provided on one side of the channel 330, and a drain electrode 342 provided on the other side of the channel 330.

A thickness of each of the source electrode 341 and the drain electrode 342 may extend from a lower surface of the gate electrode 310 to an upper surface of the channel 330. An insulator 325 may be provided between the source electrode 341 and the gate electrode 310 and between the drain electrode 342 and the gate electrode 310.

Referring to FIG. 3B, the gate insulating layer 315 may be provided to surround the gate electrode 310, and the metal nitride layer 320 may be provided to surround the gate insulating layer 315. In addition, the channel 330 may be provided to surround the metal nitride layer 320.

Comparing FIGS. 2B and 3B, FIG. 2B shows a gate last structure in which the gate electrode 240 is formed after the channel 220 is formed, and FIG. 3B shows a gate first structure in which the channel 330 is formed after the gate electrode 310 is formed. In the semiconductor devices 100, 200, and 300, the channels 120, 220, and 330 are manufactured by depositing a 2D semiconductor material, and thus, both the gate last structure and the gate first structure are possible. On the other hand, in the case of a silicon channel, the gate first structure may not be manufactured because silicon is not a deposited semiconductor.

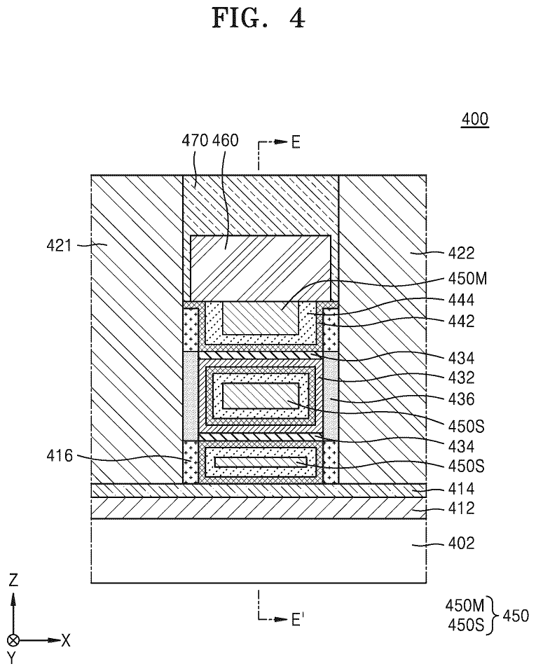

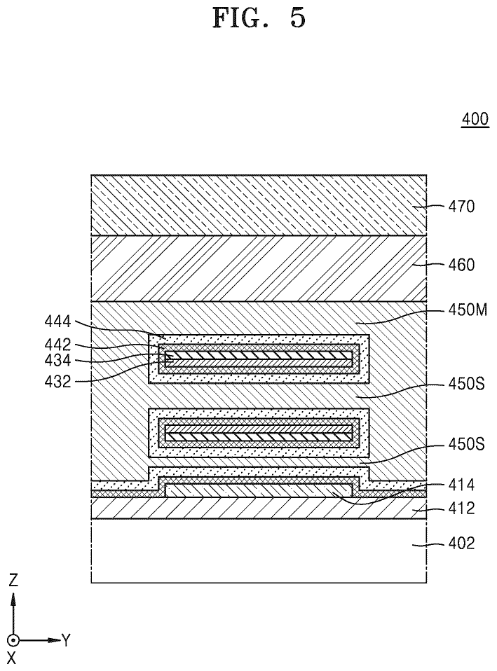

FIG. 4 is a cross-sectional view of a semiconductor device 400 according to at least one embodiment. FIG. 5 is a cross-sectional view taken along line E-E′ of FIG. 4.

The semiconductor device 400 includes a substrate 402, two metal nitride layers 434 disposed to face each other and spaced apart from the substrate 402 and each other, and a channel 432 provided between the two metal nitride layers 434. In FIG. 4, the channel 432 has a rectangular ring-shaped cross section, but the cross section is not limited thereto. The upper and lower surfaces of the channel 432 may be provided to contact the two metal nitride layers 434, respectively.

A gate electrode 450 may include a main gate portion 450M and a plurality of sub-gate portions 450S. The main gate portion 450M may be disposed on an upper portion of the channel 432 and extend in a second horizontal direction (Y direction). The plurality of sub-gate parts 450S may be integrally connected to the main gate part 450M, and disposed one by one between the metal nitride layer 434 located inside the channel 432 and on a relatively lower side of the metal nitride layer 434 and the substrate 402. In a vertical direction (Z direction), a thickness of each of the plurality of sub-gate portions 450S may be smaller than a thickness of the main gate portion 450M.

The gate electrode 450 may include conductive material, such as a metal, metal carbide, or a combination thereof. The metal may include, for example, at least one of Ti, W, Ru, Nb, Mo, Hf, Ni, Co, Pt, Yb, Tb, Dy, Er, Pd, and/or the like. The metal carbide may be TiAlC. However, a material of the gate electrode 150 is not limited thereto. The gate electrode 450 may be provided to surround four sides of the channel 432. Therefore, a facing area of the gate electrode 450 and the channel 432 increases, and thus, the short channel effect may be reduced even though a length of the channel 432 decreases.

A gate insulating layer 442 may be disposed between the gate electrode 450 and the channel 432. In at least one embodiment, the gate insulating layer 442 may have a stacked structure of an interface insulating layer and a high insulating layer. The interface insulating layer may include a low dielectric material layer having a dielectric constant of about 9 or less, for example, a silicon oxide layer, a silicon oxynitride layer, or a combination thereof. In some embodiments, the interface insulating layer may be omitted. The high insulating layer may include a material with a greater dielectric constant than that of the silicon oxide layer. For example, the high insulating layer may have a dielectric constant of about 10 to about 25. The high insulating layer may include hafnium oxide, but is not limited thereto.

A work function layer 444 may be provided between the gate insulating layer 442 and the gate electrode 450. The work function layer 444 may include, for example, a titanium nitride layer, a tantalum nitride layer, a molybdenum nitride layer, or a combination thereof.

Insulating spacers 416 may be disposed on both sidewalls of the main gate portion 450M and on both sidewalls of a sub-gate portion 150S located on a relatively lower end among a plurality of sub-gate portions 150S. The insulating spacer 416 may be spaced apart from the gate electrode 450 with the gate insulating layer 442 and the work function layer 444 disposed therebetween. The insulating spacer 416 may include an insulator, for example, silicon nitride, silicon oxide, SiCN, SiBN, SiON, SiOCN, SiBCN, SiOC, and/or a combination thereof.

A pair of vertical semiconductor layers 436 may be disposed on both sides of the channel 432. The vertical semiconductor layer 436 may extend relatively longer in the vertical direction (Z direction) than in a first horizontal direction (X direction) on a plane (e.g., X-Z plane) perpendicular to a second horizontal direction (Y direction). The pair of vertical semiconductor layers 436 may function as source/drain regions. The pair of vertical semiconductor layers 436 may be in contact with both sides of the channel 432. In some embodiments, a sidewall of the vertical semiconductor layer 436 may have a vertical length of about 5 nm to about 20 nm in the vertical direction (Z direction). In some embodiments, the vertical semiconductor layer 436 may include a 2D semiconductor material doped with impurities, a metal, and/or a multilayer 2D semiconductor material. For example, the 2D semiconductor material in vertical semiconductor layers 436 may be TMD, and the impurity may be a p-type impurity or an n-type impurity. The p-type impurity may be, for example, boron, and the n-type impurity may be, for example, phosphorus. In some embodiments, a concentration of the impurity in the vertical semiconductor layer 436 may be about 10¹⁸/cm³ to about 10²¹/cm³. In some embodiments, the vertical semiconductor layer 436 may include substantially the same material (and/or a substantially similar material) as the channel 432. For example, the channel 432 may include MoS₂, and the vertical semiconductor layer 436 may include MoS₂ doped with impurities. In some embodiments, the vertical semiconductor layer 436 may be disposed between the insulating spacers 416 in the vertical direction (Z direction). The vertical semiconductor layer 436 may reduce a contact resistance between the channel 432 and the source/drain electrodes 421 and 422.

A barrier layer 460 and an upper insulating layer 470 may be disposed on the main gate portion 450M. The barrier layer 460 may cover an upper surface of the main gate portion 450M, and the upper insulating layer 470 may cover an upper surface of the barrier layer 460. In some embodiments, the barrier layer 460 may include a metal nitride layer. For example, the metal nitride layer may be TiN. In some embodiments, the upper insulating layer 470 may include a silicon nitride layer, a silicon oxide layer, or a combination thereof.

The upper insulating layer 470 may be disposed to cover both side walls of the barrier layer 460. The source electrode 421 and the drain electrode 422 may be disposed on both sides of the channel 432 and the gate electrode 450. The source electrode 421 and the drain electrode 422 may be in contact with the vertical semiconductor layer 436.

A lower insulating layer 414 may be provided between the substrate 402 and the gate insulating layer 442. The lower insulating layer 414 may include, for example, a silicon oxide layer, a silicon nitride layer, or a combination thereof.

An etch stop layer 412 may be provided between the lower insulating layer 414 and the substrate 402. For example, the etch stop layer 412 may include a silicon oxide layer, a silicon nitride layer, or a combination thereof.

The semiconductor device 400 according to some embodiments includes the vertical semiconductor layer 436 in contact with the channel 432 and in contact with the source electrode 421 and the drain electrode 422. At this time, the vertical semiconductor layer 436 may be in contact with the source electrode 421 and the drain electrode 422 on the sidewall having a relatively large area, and thus, the resistance of the source electrode 421 and the drain electrode 422 may be alleviated. Accordingly, the electrical performance of the semiconductor device 400 including the vertical semiconductor layer 436 may be improved.

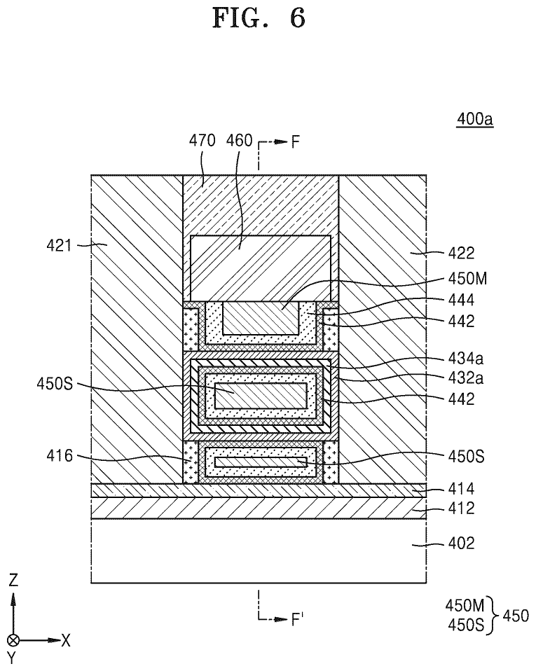

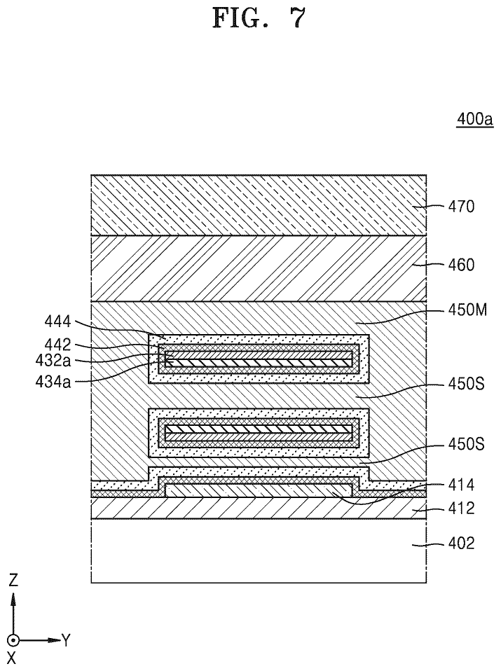

FIG. 6 is a cross-sectional view of a semiconductor device 400a according to at least one embodiment. FIG. 7 is a cross-sectional view taken along line F-F′ of FIG. 6.

Unless indicated otherwise, each component of the semiconductor device 400a illustrated in FIGS. 6 and 7 is substantially the same as each component of the semiconductor device 400 described with reference to FIGS. 5 and 6, and thus, a detailed description thereof is omitted here, and the differences are mainly described.

Referring to FIG. 6, the semiconductor device 400a may include a channel 432a between the main gate portion 450M and the sub-gate portion 450S there below. The channel 432a may have a rectangular ring-shaped cross section. The cross-sectional shape of the channel 432a is not limited thereto, and the channel 432a may have a closed ring-shaped cross section. A metal nitride layer 434a may be provided on an inner wall of the channel 432a. The metal nitride layer 434a may have a closed ring-shaped cross section along the cross-sectional shape of the channel 432a.

Compared to FIG. 5, positions and shapes of the channel 432a and the metal nitride layer 434a have been changed. Referring to FIG. 7, the channel 432a and the metal nitride layer 434a may be provided inside the gate insulating layer 442 thereon, and the channel 432a may be provided on the metal nitride layer 434a. In the semiconductor device 400a, the vertical semiconductor layer 436 is not separately provided. The channel 432a may be in direct contact with the source electrode 421 and the drain electrode 422. In the semiconductor device 400a, the channel 432a may be disposed to be in direct contact with an outer surface of the metal nitride layer 434a. In the semiconductor device 100b, four sides of the channel 432a are surrounded by the gate electrode 450.

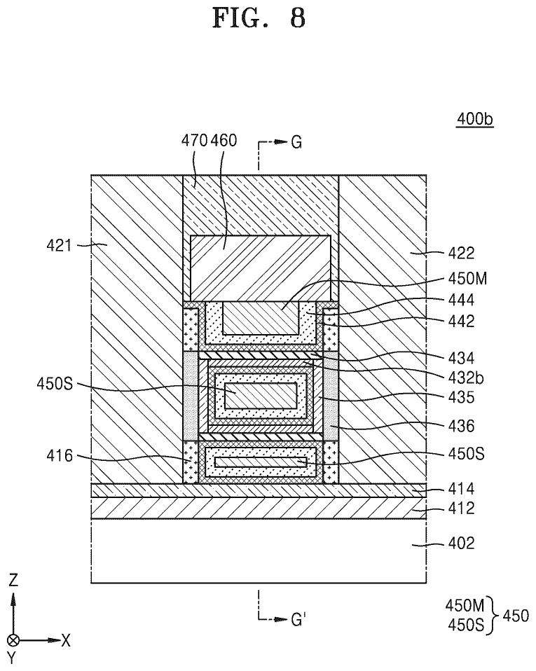

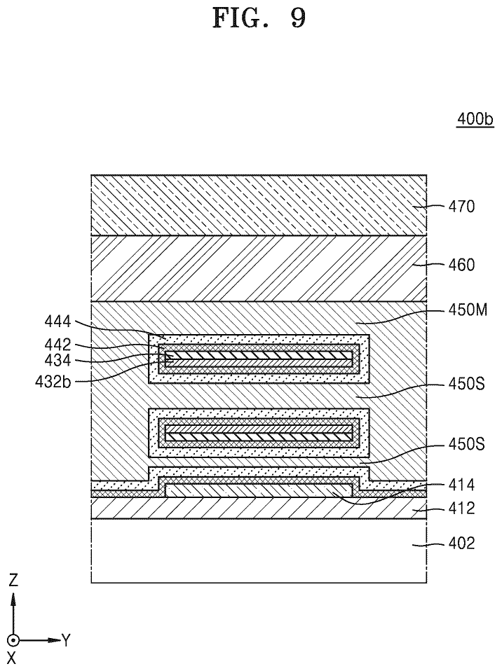

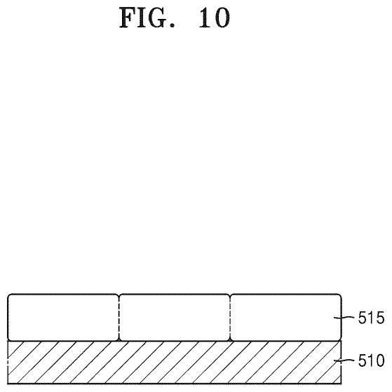

FIG. 8 is a cross-sectional view of a semiconductor device 400b according to at least one embodiment. FIG. 9 is a cross-sectional view taken along line G-G′ of FIG. 8.

Unless otherwise indicated, each component of the semiconductor device 400b illustrated in FIGS. 8 and 9 is substantially the same as (and/or substantially similar to) each component of the semiconductor device 400 described with reference to FIGS. 5 and 6, and thus, a detailed description thereof is omitted here, and the differences are mainly described.

Referring to FIG. 8, the semiconductor device 400b may include a channel 432b between the main gate portion 450M and the sub-gate portion 450S there below. The channel 432b may include two layers facing each other in the vertical direction (Z direction). The two layers of the channel 432b may have substantially the same thickness in the vertical direction (Z direction). In some embodiments, the two layers of channel 432b may have different thicknesses in the vertical direction (Z direction). For example, the channel 432b located on a relatively upper side among the channels 432b may have a greater thickness than that of the channel 432b located on a relatively lower side among the channels 432b in the vertical direction (Z direction).

In some embodiments, the two layers of channel 432b may have substantially the same (and substantially similar) size in the first horizontal direction (X direction). In some embodiments, the two layers of channel 432b may have different sizes in the first horizontal direction (X direction). The channel 432b may include a 2D semiconductor material.

The metal nitride layer 434 may be in contact with the channel 432b. For example, the metal nitride layer 434 located on a relatively upper side among the metal nitride layers 434 may be disposed on an upper surface of the channel 432b located on the relatively upper side among the channels 432b, and the metal nitride layer 434 located on a relatively lower side among the metal nitride layers 434 may be disposed on a lower surface of the channel 432b located on the relatively lower side among the channels 432b.

A width of the metal nitride layer 434 in the first horizontal direction (X direction) may be greater than a width of the channel 432b in the first horizontal direction (X direction). Accordingly, the metal nitride layer 434 may include a portion that extends in the first horizontal direction (X direction) to the outside of the channel 432b and does not overlap the channel 432b. For example, the metal nitride layer 434 may include a portion that is not in contact with the channel 432b.

A contact resistance reduction layer 435 may be provided between the metal nitride layer 434 on the upper side and the metal nitride layer 434 on the lower side in the vertical direction (Z direction). The contact resistance reduction layer 435 may include metal, a doped 2D material, or a multilayer 2D material. Four sides of the channel 432b are surrounded by the gate electrode 450.

The semiconductor devices 400 400a, and 400b may each be, for example, a gate-all-around field effect transistor (GAAFET) or a multi-bridge-channel field effect transistor (MBCFET). The semiconductor device 400 may form a logic circuit or a memory device.

Next, a method of manufacturing a semiconductor device according to at least one embodiment is described.

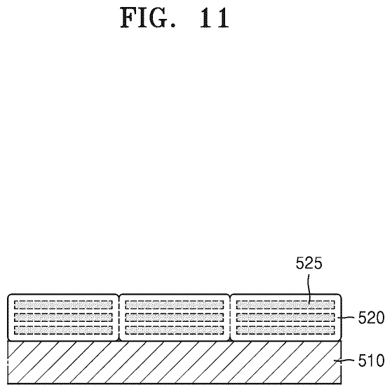

FIGS. 10 and 11 are diagrams for explaining a method of depositing a 2D semiconductor material channel on a metal nitride layer.

Referring to FIG. 10, a metal layer 515 may be deposited on a metal nitride layer 510. The metal nitride layer 510 may include metal and nitrogen. The metal nitride layer 510 may be expressed, for example, as M¹N, where M¹ represents metal and N may represent nitrogen. M¹ may include, for example, a transition metal. M¹ may include Mo, W, Nb, V, Ta, Ti, Zr, or Hf. For example, the metal nitride layer 110 may include MoN, WN, NbN, VN, TaN, TiN, ZrN, or HfN.

Alternatively, the metal nitride layer 510 may further include carbon. In this case, the metal nitride layer 510 may be expressed as M¹NC.

The metal nitride layer 510 has surface energy selected to increase a grain size of the metal layer 515. Accordingly, the grain size of the metal layer 515 may be increased by depositing the metal layer 515 on the metal nitride layer 510. The metal layer 515 may include a transition metal. The metal layer 515 may include Mo, W, Nb, V, Ta, Ti, Zr, Hf, Tc, or Re. The metal included in the metal nitride layer 510 and the metal included in the metal layer 515 may be the same material or different materials. In FIG. 10, an area divided by a dotted line in the metal layer 515 represents the grain size.

Referring to FIG. 11, a channel of a 2D semiconductor material may be formed by reacting the metal of the metal layer 515 with a chalcogen element. A channel 520 with a large grain may be generated through a process of depositing the chalcogen element on the metal layer 515 and chalcogenizing the metal layer 515. Reference number 525 denotes chalcogenized grains. When chalcogenizing the metal layer 515 with the large grain size, the size of the chalcogenized grains may also be large. In other words, compared to the case where chalcogenization is performed directly on the metal layer 515 without the metal nitride layer 510, when the metal layer 515 is deposited on the metal nitride layer 510 and then chalcogenization is performed on the deposited metal layer 515, the grain size may increase.

As described above, the channel 520 of the 2D semiconductor material is formed by increasing the grain size of the metal layer 515 and then chalcogenizing the metal layer 515, which may prevent the electrical characteristics from deteriorating even when a thickness of the channel 520 is thin. The manufacturing process described above may be applied to semiconductor devices according to some embodiments.

Hereinafter, a method of manufacturing the semiconductor device 400 shown in FIGS. 4 and 5 is described.

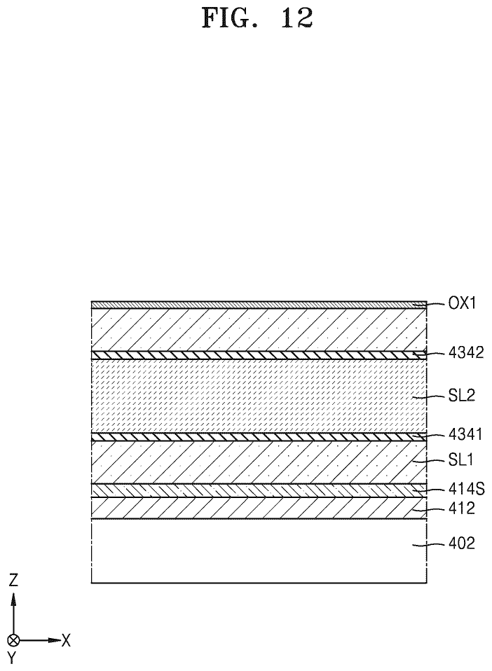

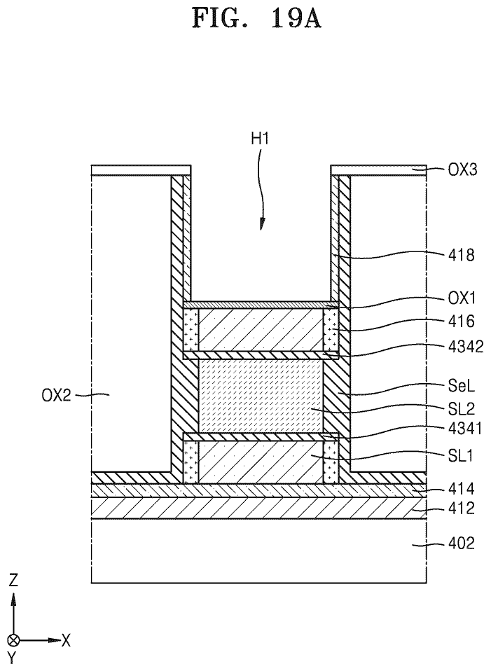

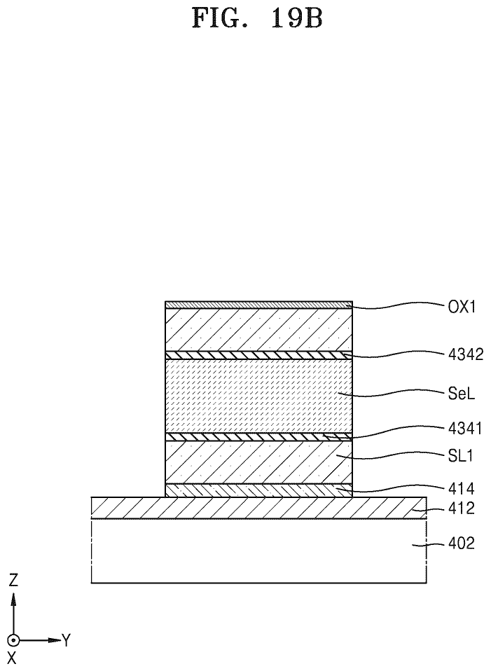

FIGS. 12 to 32 are cross-sectional views for explaining the method of manufacturing the semiconductor device 400. Specifically, FIGS. 12, 13A, 14, 15, 16, 17, 18, 19A, 20A, 21A, 22A, 23, 24, 25, 26, 27A, 28A, 29A, 30A, 31A, and 32 are cross-sectional views according to a process sequence of a part corresponding to the cross-section in FIG. 4, and FIGS. 19B, 20B, 21B, 22B, 27B, 28B, 29B, 30B, and 31B are cross-sectional views according to a process sequence of a part corresponding to the cross-section in FIG. 5. In FIGS. 12 to 32, the same reference numerals as in FIGS. 4 and 5 denote the same members, and detailed descriptions thereof are omitted.

Referring to FIG. 12, the etch stop layer 412 and a lower insulating material layer 414S are sequentially formed on the substrate 402. Next, a first sacrificial layer SL1, a first metal nitride layer 4341, a second sacrificial layer SL2, a second metal nitride layer 4342, and a first oxide layer OX1 may be sequentially formed on the lower insulating material layer 414S. The first sacrificial layer SL1 may include a semiconductor material. For example, the first sacrificial layer SL1 may include a Si layer. The second sacrificial layer SL2 may include a metal oxide layer. For example, the second sacrificial layer SL2 may include an aluminum oxide layer. The first metal nitride layer 4341 and the second metal nitride layer 4342 may each include metal and nitrogen. For example, a material of each of the first metal nitride layer 4341 and the second metal nitride layer 4342 may be expressed as M¹N, where M¹ represents metal and N may represent nitrogen. M¹ may include, for example, a transition metal. M¹ may include Mo, W, Nb, V, Ta, Ti, Zr, or Hf. The first metal nitride layer 4341 and the second metal nitride layer 4342 may each include MoN, WN, NbN, VN, TaN, TiN, ZrN, or HfN. Alternatively, the first metal nitride layer 4341 and the second metal nitride layer 4342 may each further include carbon. In this case, a material of each of the first metal nitride layer 4341 and the second metal nitride layer 4342 may be expressed as M¹NC.

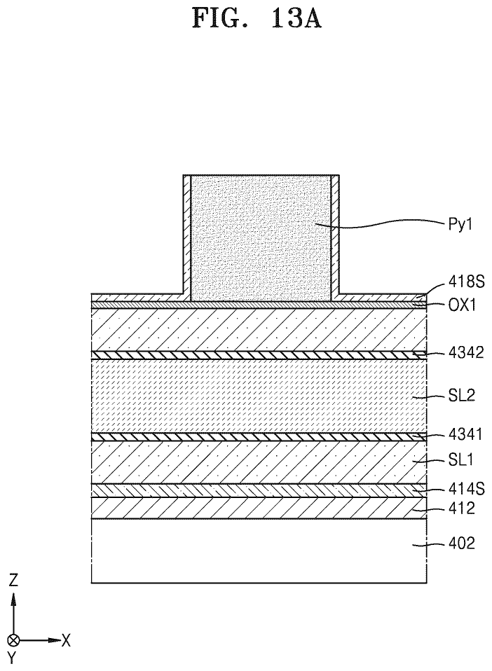

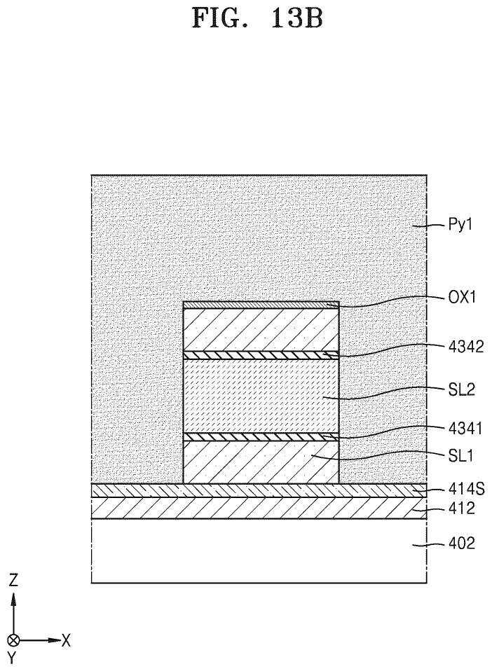

Referring to FIGS. 13A and 13B, in a result of FIG. 12, a dummy gate layer Py1 may be formed on the first oxide layer OX1, and an insulating material layer 418S covering both sidewalls of the dummy gate layer Py1 and the first oxide layer Ox1 may be formed. In some embodiments, the dummy gate layer Py1 may include polysilicon, and the insulating material layer 418S may include a silicon nitride layer.

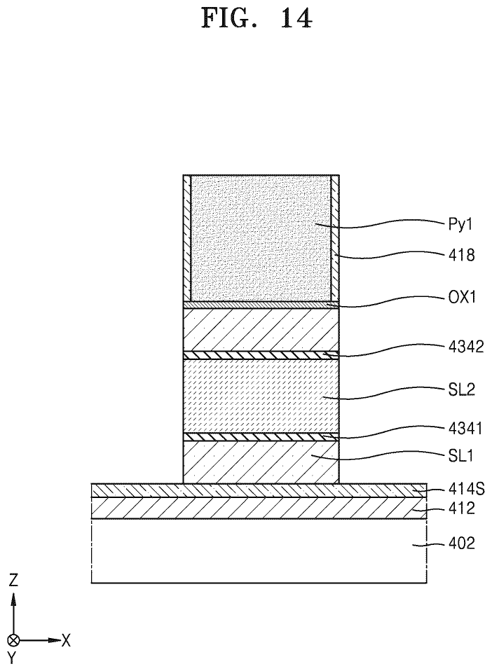

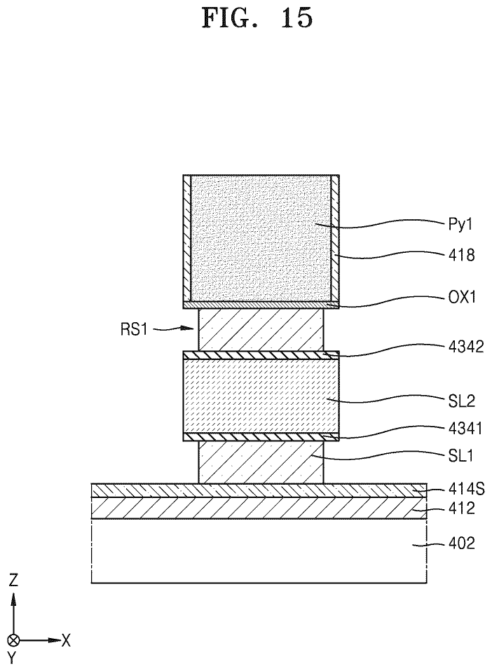

Referring to FIG. 14, in the results of FIGS. 13A and 13B, a part of each of the insulating material layer 118S, the first oxide layer OX1, the first sacrificial layer SL1, the first metal nitride layer 4341, the second sacrificial layer SL2, and the second metal nitride layer 4342 may be etched by using the dummy gate layer Py1 as an etching mask. By an etching process, the entire part of the insulating material layer 118S that covers an upper surface of the first oxide layer OX1 may be removed, only a part that covers both side walls of the dummy gate layer Py1 may remain, and may be defined as a part of the upper insulating layer 418. The etching process may be performed using, for example, dry etching, wet etching, and/or a combination thereof.

Referring to FIG. 15, in the result of FIG. 14, a first recess RS1 may be formed by partially etching the first sacrificial layer SL1 in a horizontal direction. A part of each of the first metal nitride layer 4341 and the second metal nitride layer 4342 may be exposed by the first recess RS1.

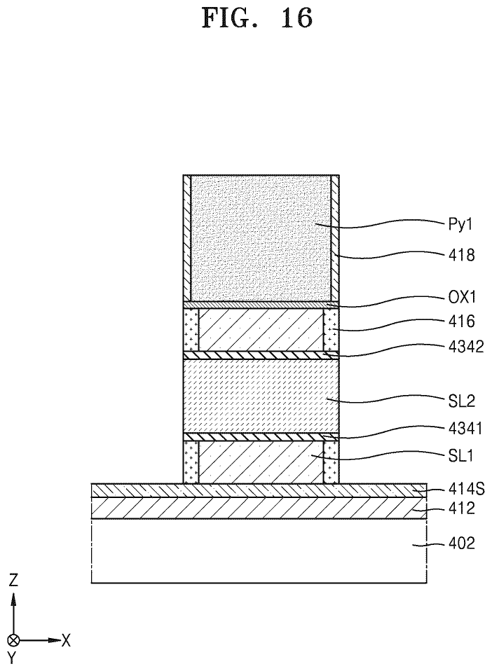

Referring to FIG. 16, in the result of FIG. 15, insulating spacers 416 that fill the first recess RS1 (see FIG. 15) may be formed. The insulating spacers 416 may be formed by forming an insulating material layer filling the first recess RS1 and covering a sidewall of the first metal nitride layer 4341, a sidewall of the second sacrificial layer SL2, a sidewall of the second metal nitride layer 4342, a sidewall of the layer OX1, and a sidewall of the upper insulating layer 418, and then removing the remaining part of the insulating material layer excluding a part filling the first recess RS1. Accordingly, a length of the insulating spacer 416 in the first horizontal direction (X direction) may be substantially equal to a length of the first recess RS1 in the first horizontal direction (X direction).

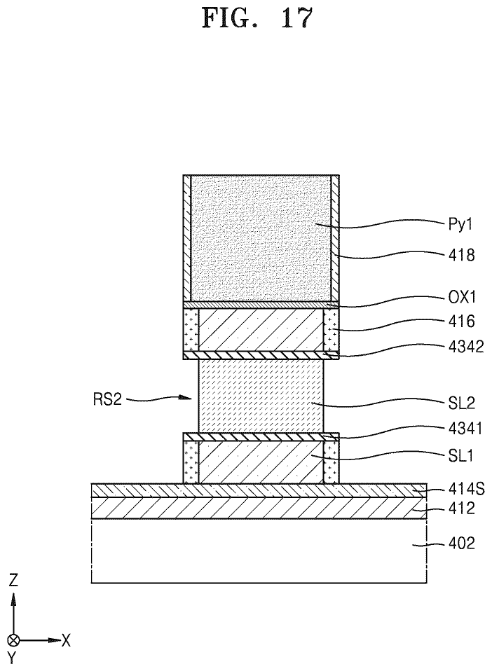

Referring to FIG. 17, in the result of FIG. 16, a second recess RS2 may be formed by partially etching the second sacrificial layer SL2 in the horizontal direction. A part of the upper surface of the first metal nitride layer 4341 and a part of the lower surface of the second metal nitride layer 4342 may be exposed by the second recess R2.

In at least one embodiment, the length of the second recess RS2 in the first horizontal direction (X direction) may be set to be substantially equal to the length of the first recess RS1 (see FIG. 15) in the first horizontal direction (X direction).

However, the disclosure is not limited thereto, and the length of the second recess RS2 in the first horizontal direction (X direction) may be set to be smaller than the length of the first recess RS1 (see FIG. 15) in the first horizontal direction (X direction).

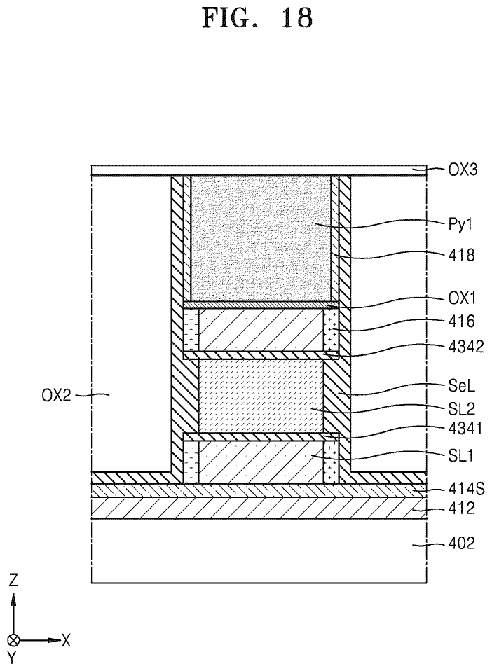

Referring to FIG. 18, in the result of FIG. 17, a seed layer SeL filling the second recess RS2 and covering the sidewall of the first metal nitride layer 4341, the sidewall of the second metal nitride layer 4342, the sidewalls of the insulating spacers 416, the sidewall of the first oxide layer OX1, the sidewall of the upper insulating layer 418, and the upper surface of the lower insulating material layer 414S may be formed. Next, a second oxide layer OX2 conformally covering a surface of the seed layer SeL may be formed, and a third oxide layer OX3 covering an upper surface of the second oxide layer OX2 and an upper surface of the dummy gate layer Py1 may be formed.

In some embodiments, the second oxide layer OX2 and the third oxide layer OX3 may each include a silicon oxide layer.

Referring to FIGS. 19A and 19B, in the result of FIG. 18, the upper surface of the dummy gate layer Py1 may be exposed by removing a part of the third oxide layer OX3 overlapping the dummy gate layer Py1 in the vertical direction (Z direction). Next, a first hole H1 may be formed by removing the exposed dummy gate layer Py1. Next, a part of the lower insulating material layer 414S exposed by the first hole H1 may be removed. At this time, a part of the remaining lower insulating material layer 414S may be defined as the lower insulating layer 414.

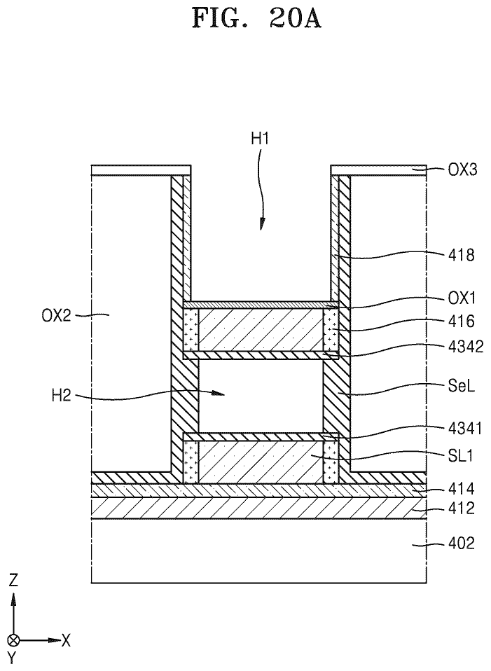

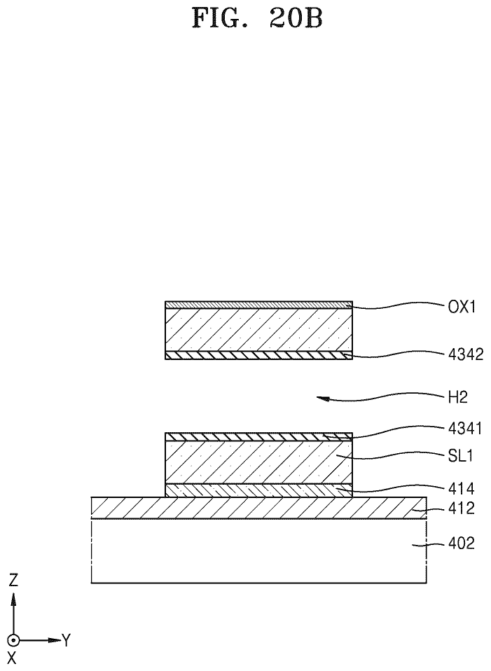

Referring to FIGS. 20A and 20B, in the results of FIGS. 19A and 19B, a second hole H2 may be formed by removing a remainder of the second sacrificial layer SL2 exposed through the first hole H1. The first hole H1 and the second hole H2 may be communicatively connected to each other.

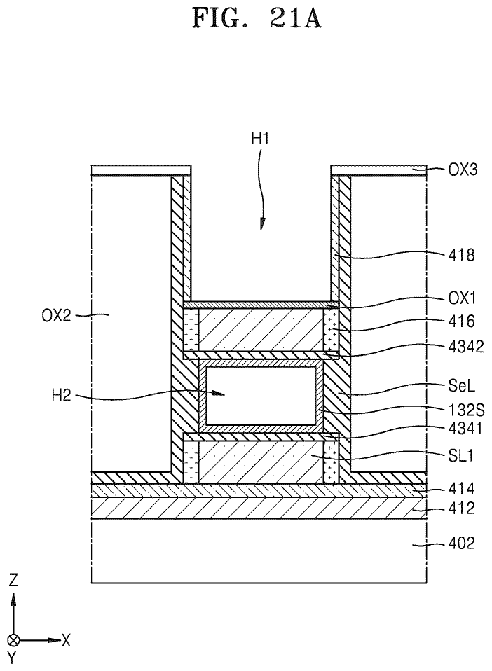

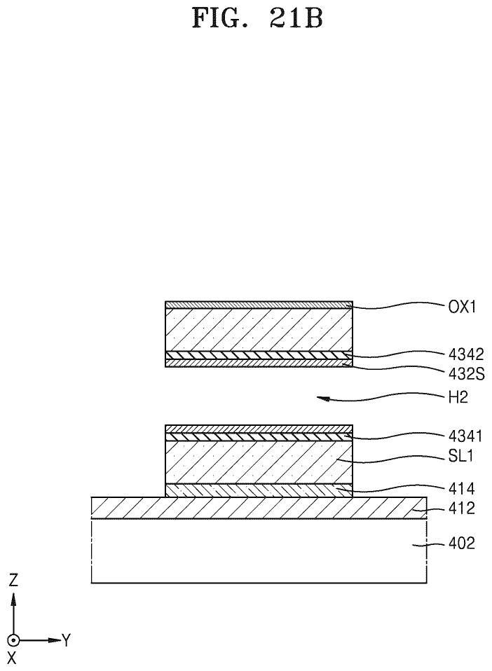

Referring to FIGS. 21A and 21B, a channel 432 may be formed in the results of FIGS. 20A and 20B. The channel 432 may be formed through the process similar to the process described with reference to FIGS. 10 and 11. For example, the metal layer may be deposited on each of the first metal nitride layer 4341 and the second metal nitride layer 4342, and then the channel 432 of a 2D semiconductor material may be formed through chalcogenation on the metal layer. Deposition and chalcogenation of the metal layer may be performed by a chemical vapor deposition (CVD), physical vapor deposition (PVD), or atomic layer deposition (ALD) process, or a combination thereof.

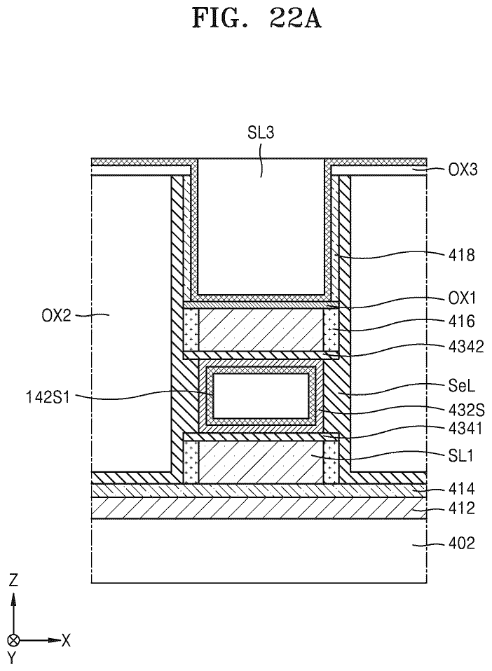

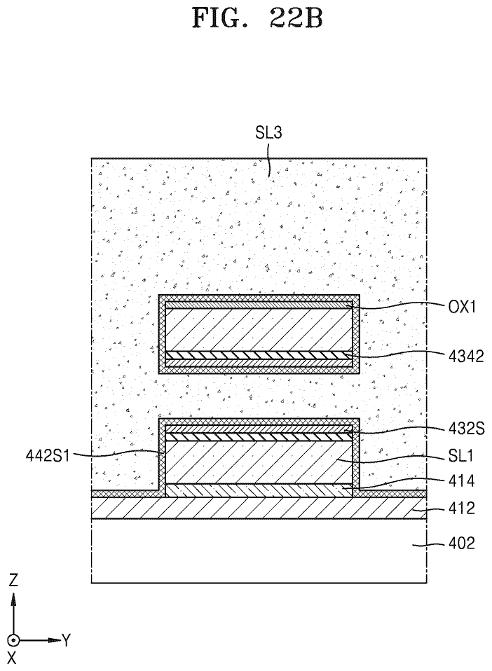

Referring to FIGS. 22A and 22B, in the results of FIGS. 21A and 21B, a dielectric material layer 442S1 covering the exposed surface of each of the first oxide layer OX1, the first sacrificial layer SL1, the channel 432, the lower insulating layer 414, and the etch stop layer 412 may be formed. In some embodiments, the dielectric material layer 442S1 may be formed using the ALD process. Next, a third sacrificial layer SL3 filling each of the first hole H1 and the second hole H2 and covering an upper surface of the third oxide layer OX3 may be formed. In some embodiments, the third sacrificial layer SL3 may include, for example, a metal oxide. In some embodiments, the third sacrificial layer SL3 may be formed using the ALD process or the CVD process.

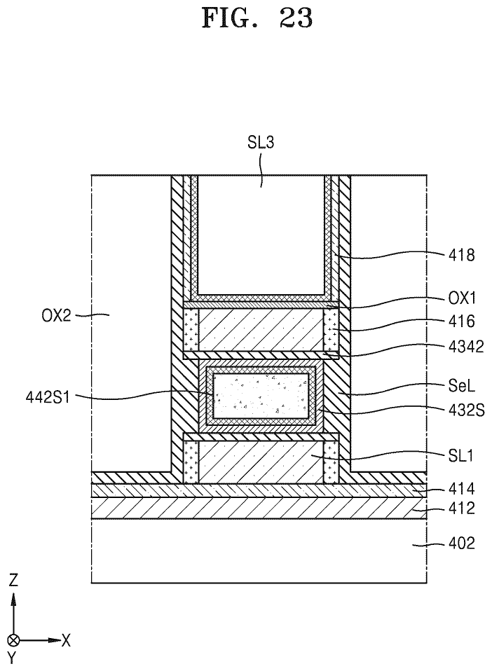

Referring to FIG. 23, in the results of FIGS. 22A and 22B, a part of the dielectric material layer 442S1, a part of the third oxide layer OX3, and a part of the third sacrificial layer SL3 may be removed. Accordingly, an upper surface of the third sacrificial layer SL3, the upper surface of the upper insulating layer 418, and the upper surface of the second oxide layer OX2 may be coplanar.

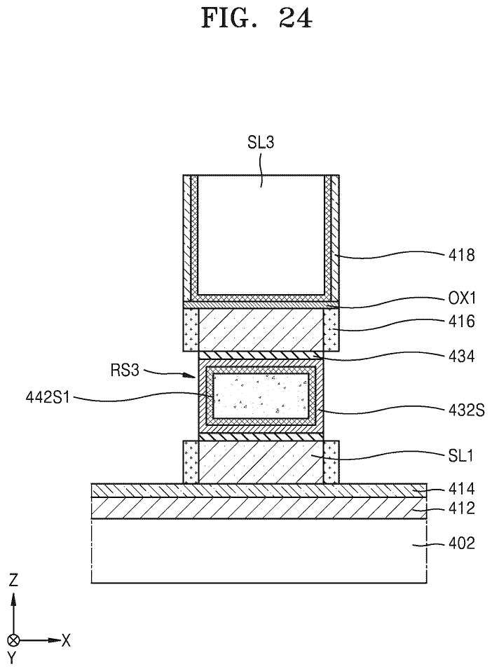

Referring to FIG. 24, the second oxide layer OX2 may be removed from the result of FIG. 23. Next, a third recess RS3 may be formed by sequentially removing the seed layer SeL exposed by removing the second oxide layer OX2 and a part of each of the first and second metal nitride layers 4341 and 4342. At this time, the first and second metal nitride layers 4341 and 4342 that remain without being removed may be defined as the metal nitride layer 434.

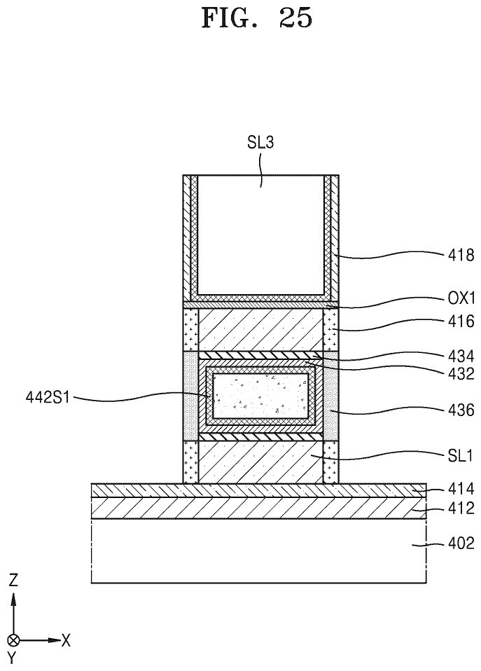

Referring to FIG. 25, in the result of FIG. 24, a vertical semiconductor layer 436 may be formed in the third recess RS3.

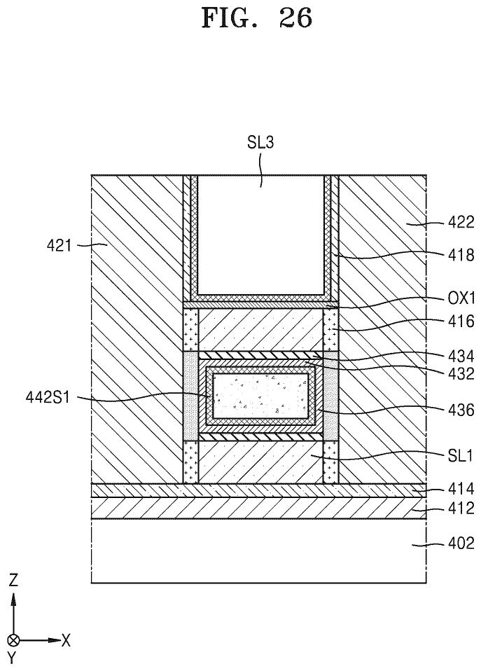

Referring to FIG. 26, in the result of FIG. 25, a source electrode 421 and a drain electrode 422 in contact with the vertical semiconductor layer 436 may be formed. The source electrode 421 and the drain electrode 422 may be formed using, for example, the ALD process or the CVD process.

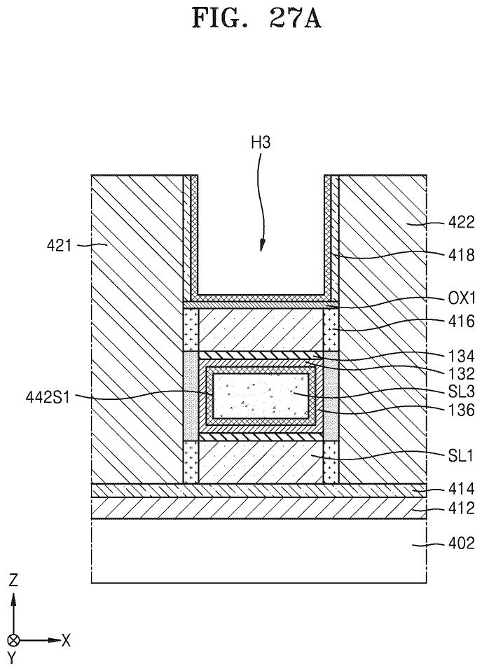

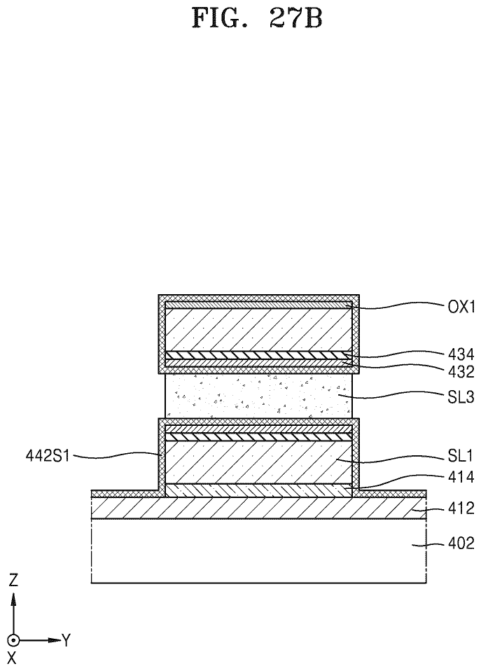

Referring to FIGS. 27A and 27B, in the result of FIG. 26, a third hole H3 may be formed by removing a part of the third sacrificial layer SL3.

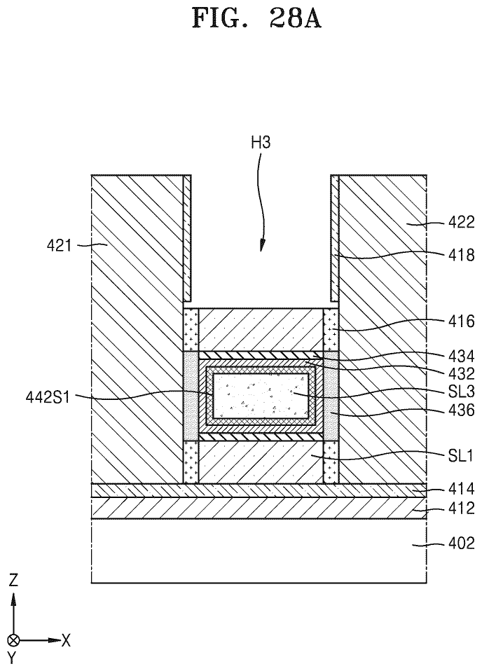

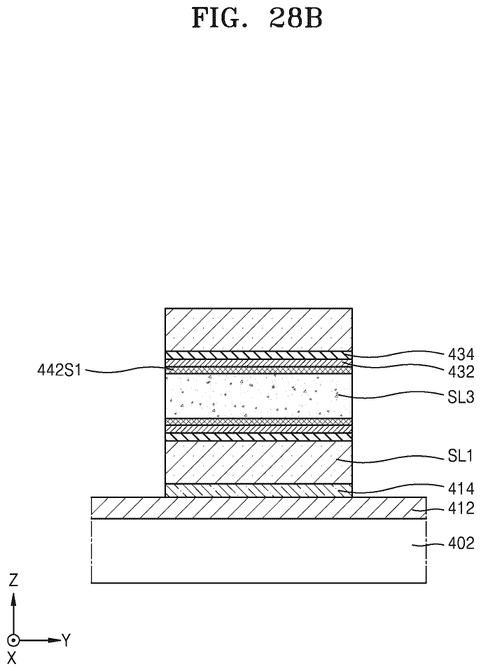

Referring to FIGS. 28A and 28B, in the results of FIGS. 27A and 27B, a part of the dielectric material layer 442S1 exposed through the third hole H3 may be removed, and the first oxide layer OX1 (see FIG. 27A) exposed by removing the part of the dielectric material layer 442S1 may be removed. The third hole H3 may expand by removing the part of the dielectric material layer 442S1 and the first oxide layer OX1.

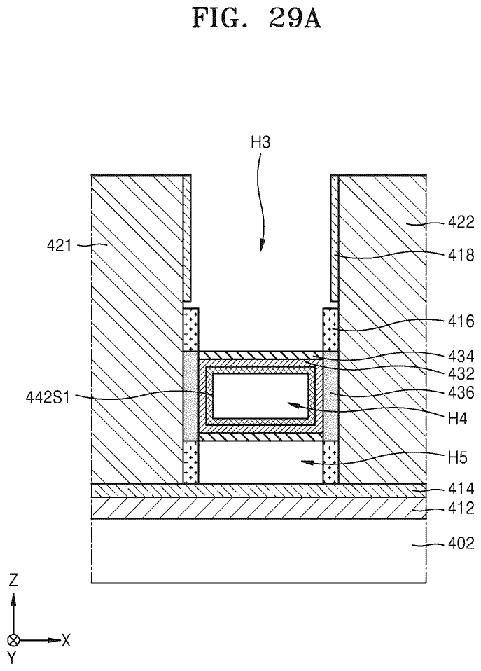

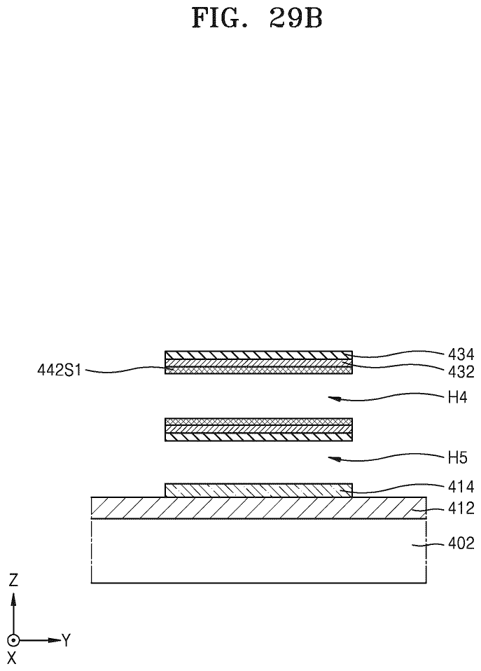

Referring to FIGS. 29A and 29B, in the results of FIGS. 28A and 28B, the first sacrificial layer SL1 (see FIG. 28A) and the third sacrificial layer SL3 may be removed through the third hole H3. The third hole H3 may expand by removing the first sacrificial layer SL1 located on a relatively upper side among the first sacrificial layers SL1. In addition, a fourth hole H4 may be formed by removing the third sacrificial layer SL, and a fifth hole H5 may be formed by removing the first sacrificial layer SL1 located on a relatively lower side among the first sacrificial layers SL1. The third hole H3, the fourth hole H4, and the fifth hole H5 may be communicatively connected to each other.

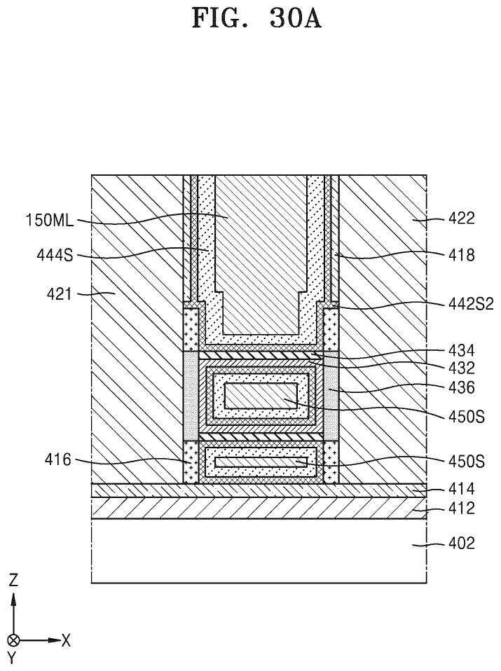

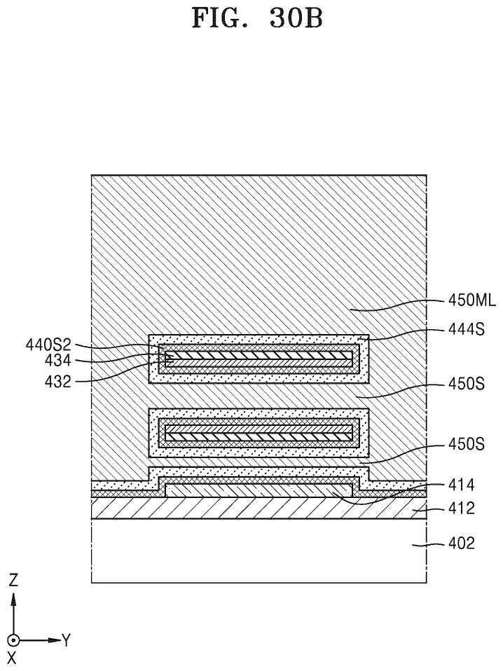

Referring to FIGS. 30A and 30B, in the results of FIGS. 29A and 29B, a dielectric material layer covering the exposed surface of each of the etch stop layer 412, the lower insulating layer 414, the metal nitride layer 434, and the channel 432 may be formed. The dielectric material layer may be defined as a first dielectric material layer 442S2 together with the remaining dielectric material layer 442S1. Next, a second dielectric material layer 444S covering a surface of the first dielectric material layer 442S2 may be formed, and a metal material layer 450L filling the third hole H3, the fourth hole H4, and the fifth hole H5 may be formed.

The first dielectric material layer 442S2 may include substantially the same material as (and/or a substantially similar material to) the dielectric material layer 442S1. For example, the dielectric material layer 442S1 and the first dielectric material layer 442S2 may include silicon oxide. The second dielectric material layer 444S may include a metal nitride layer. The metal material layer 450L may include metal, metal carbide, or a combination thereof. The metal material layer 450L may be formed using the ALD process or the CVD process.

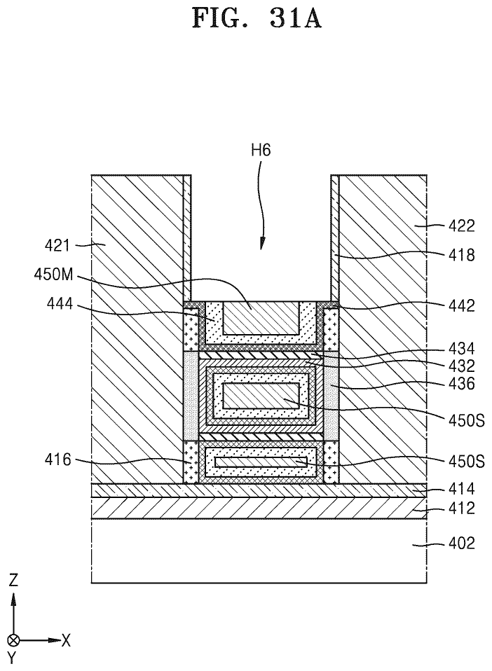

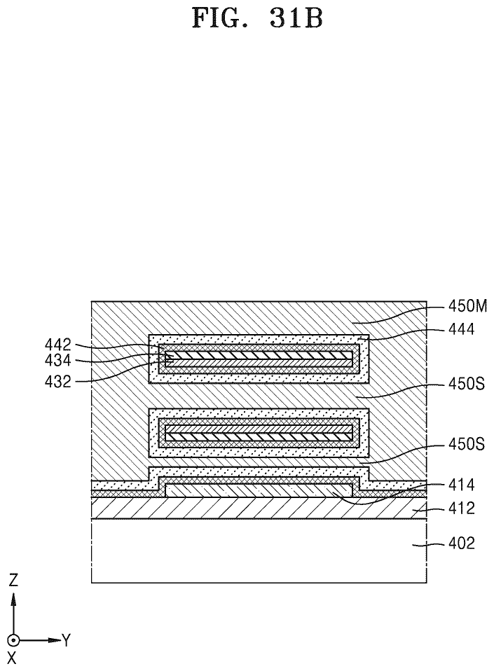

Referring to FIGS. 31A and 31B, in the results of FIGS. 30A and 30B, a part of each of the first dielectric material layer 442S2, the second dielectric material layer 444S, and the metal material layer 450L may be removed. At this time, the remaining first dielectric material layer 442S2, second dielectric material layer 444S, and metal material layer 450L may be respectively defined as a first gate insulting layer 442, a work function layer 444, and a gate electrode 450.

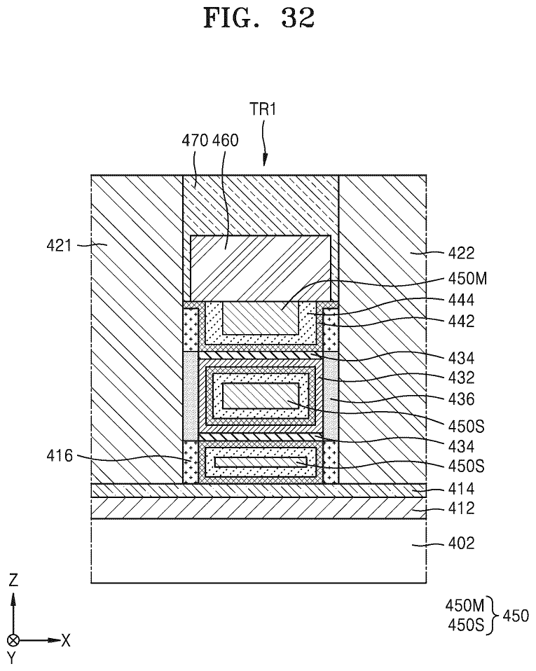

Next, referring to FIG. 32, in the results of FIGS. 31A and 31B, a barrier layer 460 and an upper insulating layer 470 may be formed in the sixth hole H6.

The semiconductor device according to at least one embodiment includes a nano-channel sheet in the form of a multi-bridge, thereby suppressing the short channel effect and effectively reducing the channel thickness and channel length. In addition, the semiconductor device according to at least one embodiment has an ultra-small size and excellent electrical performance, and thus it is suitable for application to an IC device with a high degree of integration.

The semiconductor device according to at least one embodiment may form a digital circuit or an analog circuit. In some embodiments, the semiconductor device may be used as a high voltage transistor or a low voltage transistor. For example, the semiconductor device of at least one embodiment may be configured as a high voltage transistor that constitutes a peripheral circuit of a flash memory device or an electrically operable and programmable read only memory (EEPROM) device, which is a nonvolatile memory device that operates at a high voltage. Alternatively, the semiconductor device of at least one embodiment may be configured as a transistor including an IC device for a liquid crystal display (LCD) that requires an operating voltage of 10 V or more, for example, about 20 V to about 30 V, or an IC chip used in a plasma display panel (PDP) that requires an operating voltage of 100 V.

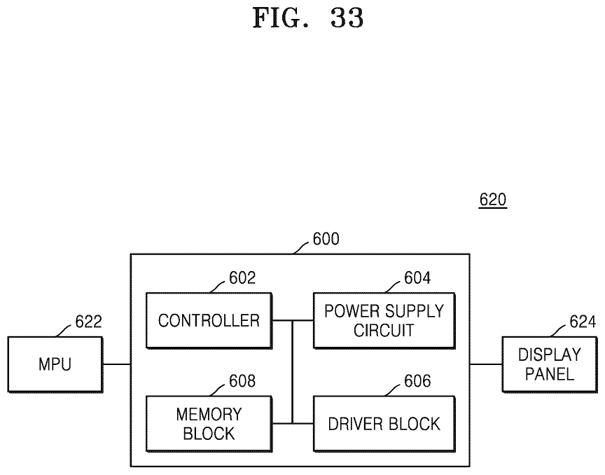

FIG. 33 is a schematic block diagram of a display device 620 including a display driver integrated circuit (DDI) 600 according to at least one embodiment.

Referring to FIG. 33, the DDI 600 may include a controller 602, a power supply circuit 604, a driver block 606, and a memory block 608. The controller 602 may receive and decode commands issued from a main processing unit (MPU) 522, and control each block of the DDI 600 to implement operations according to the commands. The power supply circuit 604 generates a driving voltage in response to the control of the controller 602. The driver block 606 drives a display panel 524 by using the driving voltage generated by the power supply circuit 604 in response to the control of the controller 602. The display panel 524 may be a liquid crystal display panel or a plasma display panel. The memory block 608 is a block that temporarily stores commands input to the controller 602 or control signals output from the controller 602, or stores necessary data, and may include memory such as RAM or ROM. The power supply circuit 604 and the driver block 606 may each include the semiconductor devices 100, 200, 300, 400, 400a, and 400b according to the embodiments described above with reference to FIGS. 1A to 9.

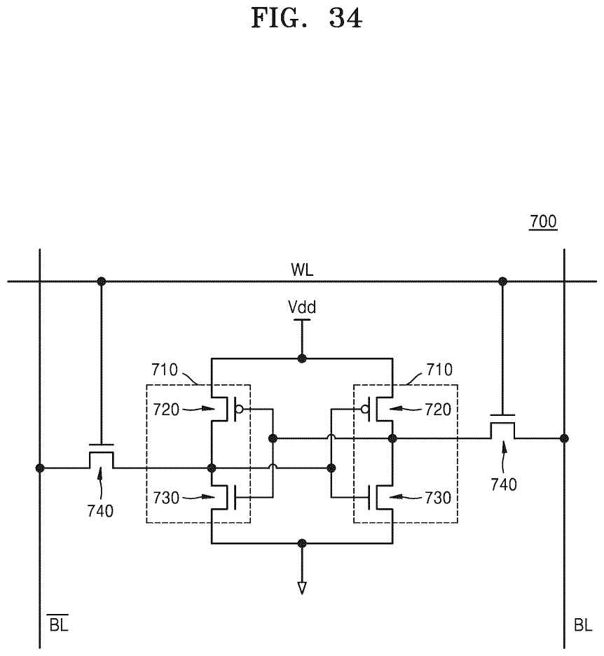

FIG. 34 is a circuit diagram of a CMOS SRAM device 700 according to at least one embodiment.

The CMOS SRAM device 700 includes a pair of driving transistors 710. The pair of driving transistors 710 each includes a PMOS transistor 720 and an NMOS transistor 730 connected between the power terminal Vdd and a ground terminal. The CMOS SRAM device 700 may further include a pair of transfer transistors 740. Sources of the transfer transistors 740 are cross-connected to a common node of the PMOS transistors 720 and the NMOS transistors 730 included in the driving transistors 710. The power terminal Vdd is connected to a source of the PMOS transistor 720, and the ground terminal is connected to a source of the NMOS transistor 730. A word line WL may be connected to a gate of the pair of transfer transistors 740, and a bit line BL and an inverted bit line may be respectively connected to drains of the pair of transfer transistors 740.

At least one of the driving transistors 710 and the transfer transistors 740 of the CMOS SRAM device 700 may include the semiconductor devices 100, 200, 300, 400, 400a, and 400b according to the embodiments described above with reference to FIGS. 1A to 9.

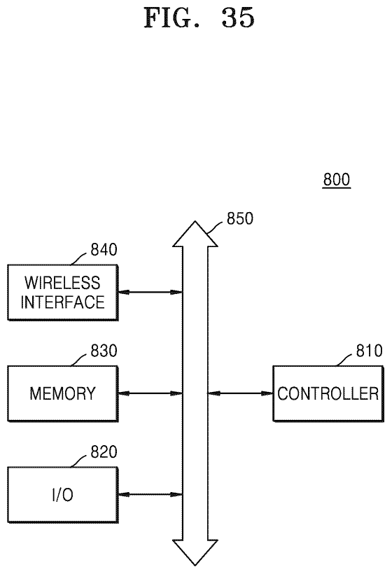

FIG. 35 is a block diagram of an electronic device 800 according to at least one embodiment.

The electronic device 800 may configure a wireless communication device, or a device capable of transmitting and/or receiving information in a wireless environment. The electronic device 800 includes a controller 810, an input/output device (I/O) 820, a memory 830, and a wireless interface 840, which are interconnected via a bus 850.

The controller 810 may include at least one of a microprocessor, a digital signal processor, or a processing device similar to these. The input/output device 820 may include at least one of a keypad, a keyboard, or a display. The memory 830 may be used to store commands executed by controller 810. For example, the memory 830 may be used to store user data. The electronic device 800 may use the wireless interface 840 to transmit/receive data over a wireless communication network. The wireless interface 840 may include an antenna and/or a wireless transceiver. In some embodiments, the electronic device 800 may be used in a communication interface protocol of a third generation communication system, such as code division multiple access (CDMA), global system for mobile communications (GSM), north American digital cellular (NADC), extended-time division multiple access (E-TDMA), and/or wide band code division multiple access (WCDMA). The electronic device 800 may include the semiconductor devices 100, 200, 300, 400, 400a, and 400b according to the embodiments described above with reference to FIGS. 1A to 9.

The semiconductor device according to at least one embodiment may exhibit good electrical performance with an ultra-small structure, be applied to an IC device, and implement miniaturization, low power, and high performance.

The semiconductor device according to at least one embodiment includes a channel of a 2D semiconductor material in a metal nitride layer, thereby improving performance of the channel while reducing a thickness of the channel.

In the method of manufacturing the semiconductor device according to at least one embodiment, the channel of the 2D semiconductor material may be formed by depositing a metal layer on the metal nitride layer to increase the grain size of the metal and then chalcogenizing the metal. The metal nitride has surface energy capable of increasing the grain size of the metal to be subsequently deposited, and thus, the channel with a large grain may be generated through a process of sequentially depositing the metal nitride, depositing the metal, and performing chalcogenization.

It should be understood that the embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a metal nitride layer;
a channel on a surface the metal nitride layer, the channel comprising a two-dimensional (2D) semiconductor material;
a source electrode on a first side of the channel;
a drain electrode on a second side of the channel;
a gate insulating layer on the channel; and
a gate electrode on the gate insulating layer such that the gate insulating layer is between the gate electrode and the channel.

2. The semiconductor device of claim 1, wherein the metal nitride layer includes a transition metal and nitrogen.

3. The semiconductor device of claim 2, wherein the metal nitride layer includes a material expressed as M¹N, where M¹ represents the transition metal and includes at least one of Mo, W, Nb, V, Ta, Ti, Zr, or Hf, and N represents the nitrogen.

4. The semiconductor device of claim 1, wherein the metal nitride layer has a thickness greater than 0 and about 3 nm or less.

5. The semiconductor device of claim 1, wherein the channel includes a material expressed as M²X₂, where M² represents at least one of Mo, W, Nb, V, Ta, Ti, Zr, Hf, Tc, or Re, and X represents at least one of S, Se, or Te.

6. The semiconductor device of claim 1, wherein the channel includes at least one of MoS₂, MoSe₂, MoTe₂, WS₂, WSe₂, WTe₂, ZrS₂, ZrSe₂, HfS₂, HfSe₂, NbSe₂, or ReSe₂.

7. The semiconductor device of claim 1, wherein the metal nitride layer further includes carbon.

8. The semiconductor device of claim 1, wherein the channel is in direct contact with the metal nitride layer.

9. The semiconductor device of claim 1, wherein the channel includes a stack of 1 or more and 10 or less 2D semiconductor material layers.

10. A method of manufacturing a semiconductor device, the method comprising:
depositing a metal layer on a surface of a metal nitride layer;
forming a channel of a two-dimensional (2D) semiconductor material by reacting a metal of the metal layer with a chalcogen element;
forming a source electrode on a first side of the channel and forming a drain electrode on a second side of the channel;
forming a gate insulating layer on the channel; and
forming a gate electrode on the gate insulating layer such that the gate insulating layer is between the gate electrode and the channel.

11. The method of claim 10, wherein the metal nitride layer includes a transition metal and nitrogen.

12. The method of claim 11, wherein the metal nitride layer includes a material expressed as M¹N, where M¹ represents the transition metal and includes at least one of Mo, W, Nb, V, Ta, Ti, Zr, or Hf, and N represents the nitrogen.

13. The method of claim 10, wherein the metal nitride layer has a thickness greater than 0 and about 3 nm or less.

14. The method of claim 10, wherein the channel includes a material expressed as M²X₂, where M² represents at least one of Mo, W, Nb, V, Ta, Ti, Zr, Hf, Tc, or Re, and X represents at least one of S, Se, or Te.

15. The method of claim 10, wherein the channel includes at least one of MoS₂, MoSe₂, MoTe₂, WS₂, WSe₂, WTe₂, ZrS₂, ZrSe₂, HfS₂, HfSe₂, NbSe₂, or ReSe₂.

16. The method of claim 10, wherein the metal nitride layer further includes carbon.

17. The method of claim 10, wherein the channel is disposed to be in direct contact with the metal nitride layer.

18. The method of claim 10, wherein the forming the channel includes forming the channel to include a stack of 1 or more and 10 or less 2D semiconductor material layers.

19. The method of claim 10, wherein the forming of the channel is performed using at least one of a chemical vapor deposition (CVD), physical vapor deposition (PVD), or atomic layer deposition (ALD) process.
